(19) United States
(12) Patent Application Publication
(10) Pub. No.: US 2016/0247847 A1
(43) Pub. Date: Aug. 25, 2016

(54) SEMICONDUCTOR DEVICE, IMAGING APPARATUS, AND METHOD OF MANUFACTURING SEMICONDUCTOR DEVICE

(71) Applicants: Yoshinori Ueda, Hyogo (JP); Kazuhiro Yoneda, Osaka (JP); Katsuhiko Aisu, Hyogo (JP); Yasukazu Nakatani, Hyogo (JP); Takaaki Negoro, Osaka (JP); Katsuyuki Sakurano, Hyogo (JP); Hirofumi Watanabe, Hyogo (JP)

(72) Inventors: Yoshinori Ueda, Hyogo (JP); Kazuhiro Yoneda, Osaka (JP); Katsuhiko Aisu, Hyogo (JP); Yasukazu Nakatani, Hyogo (JP); Takaaki Negoro, Osaka (JP); Katsuyuki Sakurano, Hyogo (JP); Hirofumi Watanabe, Hyogo (JP)

(73) Assignee: RICOH COMPANY, LTD., Tokyo (JP)

(21) Appl. No.: 15/019,451

(22) Filed: Feb. 9, 2016

(30) Foreign Application Priority Data
Feb. 19, 2015 (JP) 2015-030362

(51) Int. Cl. H01L 27/146

(52) U.S. Cl. CPC H01L 27/14614; H01L 27/14683

(57) ABSTRACT

A semiconductor device includes a semiconductor layer, an electrode embedded from a surface of the semiconductor layer to an inside of the semiconductor layer and insulated by an insulation layer, and a structure in which a first semiconductor region of a first conductivity type, a second semiconductor region of a second conductivity type, and a third semiconductor region of the first conductivity type are formed in this order from the surface of the semiconductor layer along the electrode via the insulation layer. The electrode is arranged at a position where no inversion layer is formed by a voltage supplied to the electrode in at least one of an interface of the first semiconductor region and the second semiconductor region and an interface of the second semiconductor region and the third semiconductor region.

### CROSS-REFERENCE TO RELATED APPLICATION

The present application is based upon and claims the benefit of priority of Japanese Patent Application No. 2015-030362, filed on Feb. 19, 2015, the contents of which are incorporated herein by reference in their entirety.

### BACKGROUND OF THE INVENTION

1. Field of the Invention

The present invention relates to a semiconductor device, an imaging apparatus, and a method of manufacturing a semiconductor device.

2. Description of the Related Art

Photodiodes are frequently used as photodetectors because they can be manufactured by a simple process and can output a stable photoelectric current for detection. However, a photoelectric current generated by the existing photodiodes at a time of light irradiation is weak, and a photodiode having a large light-receiving area is required in order to provide a good light-receiving sensitivity at a low illumination.

A phototransistor having a bipolar transistor structure is capable of amplifying a photoelectric current by utilizing a physical property of the bipolar transistor structure when the photoelectric current is generated by a photodiode formed between a collector and a base and output from an emitter in the phototransistor. A phototransistor (semiconductor device) having a vertical bipolar transistor structure is known and in this phototransistor a photoelectric current relative to light intensity can be varied by varying the current amplification factor using the above-described feature. For example, see Japanese Laid-Open Patent Publication No. 2013-187527.

A semiconductor device according to the related art has a problem that leakage current resulting from a parasitic MOS (metal oxide semiconductor) transistor is increased when the current amplification factor is increased.

### SUMMARY OF THE INVENTION

In one aspect, the present invention provides a semiconductor device which is capable of providing an increased current amplification factor and preventing the leakage current.

In one embodiment, the present invention provides a semiconductor device including a semiconductor layer, an electrode embedded from a surface of the semiconductor layer to an inside of the semiconductor layer and insulated by an insulation layer, and a structure in which a first semiconductor region of a first conductivity type, a second semiconductor region of a second conductivity type, and a third semiconductor region of the first conductivity type are formed in this order from the surface of the semiconductor layer along the electrode via the insulation layer, wherein the electrode is arranged at a position where no inversion layer is formed by a voltage supplied to the electrode in at least one of an interface of the first semiconductor region and the second semiconductor region and an interface of the second semiconductor region and the third semiconductor region.

The object and advantages of the invention will be implemented and attained by means of the elements and combinations particularly pointed out in the claims. It is to be understood that both the foregoing general description and the following detailed description are exemplary and explanatory and are not restrictive of the invention as claimed.

### BRIEF DESCRIPTION OF THE DRAWINGS

FIG. 1 is a cross-sectional view of a semiconductor device according to an embodiment.

FIG. 2 is a plan view of the semiconductor device according to the embodiment.

FIGS. 3A to 3C are diagrams for explaining a method of manufacturing the semiconductor device according to the embodiment.

FIGS. 4A to 4C are diagrams for explaining the method of manufacturing the semiconductor device according to the embodiment after a step shown in FIG. 3C is performed.

FIGS. 5A and 5B are diagrams for explaining the method of manufacturing the semiconductor device according to the embodiment after a step shown in FIG. 4C is performed.

FIG. 6 is a cross-sectional view of a photodetector as a reference example.

FIG. 7 is a diagram for explaining a relationship between illuminance and photoelectric current of a photodetector having a vertical bipolar transistor structure according to a gate electrode voltage of the photodetector.

FIG. 8 is a cross-sectional view of a photodetector according to another embodiment.

FIG. 9 is a cross-sectional view of a photodetector according to another embodiment.

FIG. 10 is a cross-sectional view of a photodetector according to another embodiment.

FIG. 11 is a cross-sectional view of a photodetector according to another embodiment.

FIG. 12 is a cross-sectional view of a photodetector according to another embodiment.

FIG. 13 is a cross-sectional view of a photodetector according to another embodiment.

FIG. 14 is a cross-sectional view of a photodetector according to another embodiment.

### DETAILED DESCRIPTION OF THE PREFERRED EMBODIMENTS

In the following, a first conductivity type used in a semiconductor device of the invention may be a P type or an N type, and a second conductivity type which is opposite to the first conductivity type may be an N type or a P type.

In one aspect, the semiconductor device of the invention includes a semiconductor layer, an electrode embedded from a surface of the semiconductor layer to an inside of the semiconductor layer and insulated by an insulation layer, and a structure in which a first semiconductor region of a first conductivity type, a second semiconductor region of a second conductivity type, and a third semiconductor region of the first conductivity type are formed in this order from the surface of the semiconductor layer along the electrode via the insulation layer, wherein the electrode may be arranged at a position where no inversion layer is formed by a voltage supplied to the electrode in at least one of an interface of the first semiconductor region and the second semiconductor region and an interface of the second semiconductor region and the third semiconductor region.

In another aspect, the semiconductor device of the invention includes a semiconductor layer, an electrode embedded from a surface of the semiconductor layer to an inside of the semiconductor layer and insulated by an insulation layer, and a structure in which a first semiconductor region of a first conductivity type, a second semiconductor region of a second conductivity type, and a third semiconductor region of the first conductivity type are formed in this order from the surface of the semiconductor layer along the electrode via the insulation layer, wherein at least one of a distance between the electrode and an interface of the first semiconductor region and the second semiconductor region and a distance between the electrode and an interface of the second semiconductor region and the third semiconductor region may be greater than a distance between the electrode and the second semiconductor region.

Here, each of the distance between the electrode and the interface of the first semiconductor region and the second semiconductor region, the distance between the electrode and the interface of the second semiconductor region and the third semiconductor region, and the distance between the electrode and the second semiconductor region refers to a smallest distance between them.

In one embodiment of the semiconductor device, with respect to a positional relationship between the electrode and the first semiconductor region in a depth direction, an upper end of the electrode may be located at a position below a bottom of the first semiconductor region.

In another embodiment of the semiconductor device, with respect to a positional relationship between the electrode and the third semiconductor region in a depth direction, a lower end of the electrode may be located at a position above a top of the third semiconductor region.

In another embodiment of the semiconductor device, with respect to a positional relationship between the electrode, the first semiconductor region, and the second semiconductor region in a horizontal direction, a distance between the electrode and a bottom of the first semiconductor region may be greater than a distance between the electrode and the second semiconductor region. Specifically, in this embodiment, a cross-sectional shape of the electrode may be either a trapezoidal shape in which an upper base is smaller in width than a lower base or a convex configuration including an upward convex portion on an upper side of the configuration. However, the cross-sectional shape of the electrode is not limited to this embodiment.

In another embodiment of the semiconductor device, with respect to a positional relationship between the electrode, the second semiconductor region, and the third semiconductor region in a horizontal direction, a distance between the electrode and a top of the third semiconductor region may be greater than a distance between the electrode and the second semiconductor region. Specifically, in this embodiment, a cross-sectional shape of the electrode may be either a trapezoidal shape in which an upper base is greater in width than a lower base or a convex configuration including a downward convex portion on a lower side of the configuration. However, the cross-sectional shape of the electrode is not limited to this embodiment.

The semiconductor device of the invention may include any combinations of the foregoing embodiments. Note that the semiconductor device of the invention is not limited to the foregoing embodiments and the combinations of the foregoing embodiments.

In another embodiment of the semiconductor device, a current amplification factor of the semiconductor device may be variable depending on an amplitude of the voltage supplied to the electrode.

In another embodiment of the semiconductor device, the electrode may be provided to have a frame configuration in a plan view of the semiconductor layer. However, the configuration of the electrode is not limited to this embodiment.

An imaging apparatus according to the invention may include a photodetector which is constituted by the semiconductor device of the foregoing embodiments. Examples of the imaging apparatus may include a camera, an in-vehicle camera, a medical-use camera, a vein authentication camera, an infrared camera, etc. However, the imaging apparatus according to the invention is not limited to these examples.

In a method of manufacturing a semiconductor device according to the invention, the semiconductor device includes a semiconductor layer, an electrode embedded from a surface of the semiconductor layer to an inside of the semiconductor layer and insulated by an insulation layer, and a structure in which a first semiconductor region of a first conductivity type, a second semiconductor region of a second conductivity type, and a third semiconductor region of the first conductivity type are formed in this order from the surface of the semiconductor layer along the electrode via the insulation layer. The method of manufacturing the semiconductor device may include arranging the electrode at a position where no inversion layer is formed by a voltage supplied to the electrode, in at least one of an interface of the first semiconductor region and the second semiconductor region and an interface of the second semiconductor region and the third semiconductor region.

The semiconductor device according to the invention will be described. In the following, a gate electrode embedded in the semiconductor device corresponds to the electrode embedded therein, an emitter region in the semiconductor device corresponds to the first semiconductor region, a base region in the semiconductor device corresponds to the second semiconductor region, and a collector region in the semiconductor device corresponds to the third semiconductor region.

In the semiconductor device according to the invention, a parasitic MOS transistor may be formed in a portion of the embedded gate electrode. Further, in the semiconductor device according to the invention, at least one of the emitter region and the collector region are located at a position farther from the embedded gate electrode than the base region. Hence, in the structure of the parasitic MOS transistor which may be formed by the embedded gate electrode with the emitter region, the base region, and the collector region, dark current (leakage current) does not flow between the emitter and the collector.

Further, in the semiconductor device according to the invention, when a structure in which the collector region is separated from the embedded gate electrode is used, it is possible to prevent also the flowing of a dark current from the collector region to the base region which may be caused by the electric field of the gate electrode.

Accordingly, the semiconductor device according to the invention may provide an increased current amplification factor and prevent the dark current (leakage current). When used as a photodetector, the semiconductor device according to the invention may provide an increased light-receiving sensitivity at a time of light irradiation.

In the semiconductor device according to the invention, the base-width modulation effect of the depletion layer to the base region by the embedded gate electrode remains unchanged while the dark current is prevented effectively. Hence, in the semiconductor device according to the invention, it is possible to change the base region into the depletion region by the voltage supplied to the gate electrode without increasing the dark current caused by the parasitic MOS transistor and it is possible to vary the current amplification factor.

Next, semiconductor devices according to several embodiments will be described in greater detail with reference to the accompanying drawings.

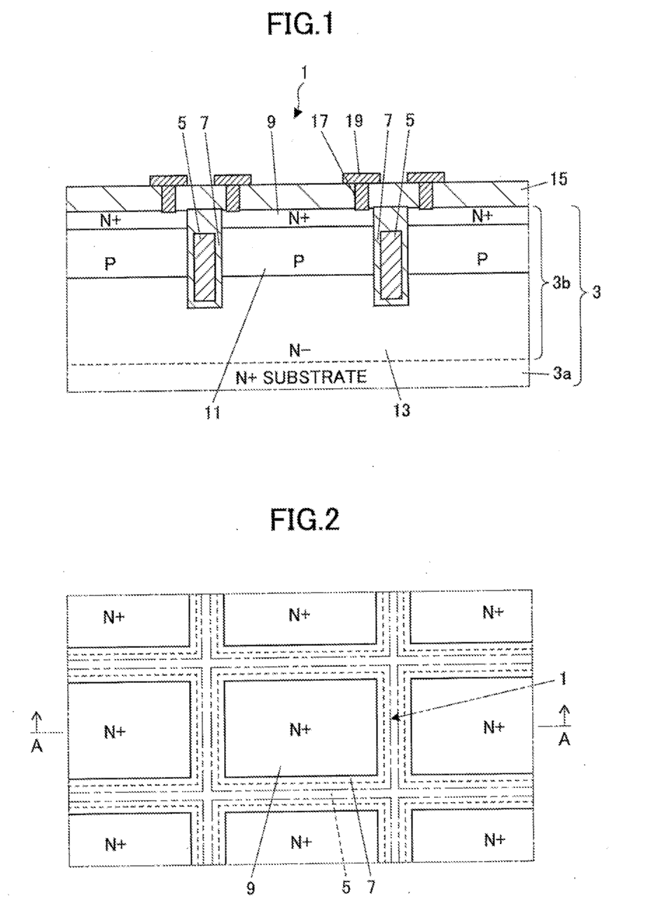

FIG. 1 is a cross-sectional view of a semiconductor device 1 according to an embodiment. FIG. 2 is a plan view of the semiconductor device 1 according to the embodiment. The cross-sectional view of FIG. 1 corresponds to a cross-section of the semiconductor device taken along a line A-A indicated in FIG. 2. In FIG. 2, the illustration of an upper layer structure formed on a semiconductor substrate in the semiconductor device is omitted for the sake of description.

As shown in FIGS. 1 and 2, a plurality of photodetectors (semiconductor devices) 1 are fabricated on a semiconductor substrate 3. For example, the semiconductor substrate 3 includes an N type silicon substrate 3a (N+ substrate) in which an N type impurity is introduced, and an N type epitaxial layer 3b (semiconductor layer) formed on a surface of the silicon substrate 3a by epitaxial growth. Note that a semiconductor layer in the semiconductor device according to the embodiment is not limited to the epitaxial layer. The semiconductor layer in the semiconductor device according to the embodiment may be a bulk silicon layer, or may be a semiconductor layer made of a semiconductor material other than silicon. Further, the semiconductor layer in the semiconductor device according to the embodiment may be two or more laminated semiconductor layers.

For example, the photodetectors 1 are arrayed in a matrix formation. Each of the photodetectors 1 includes a gate electrode 5 (electrode), a gate insulation film 7 (insulation layer), an emitter region 9 (first semiconductor region), a base region 11 (second semiconductor region), and a collector region 13 (third semiconductor region).

The gate electrode 5 is arranged so that the gate electrode 5 is embedded in the epitaxial layer 3b from a surface of the epitaxial layer 3b to the inside of the epitaxial layer 3b. For example, a trench (slot) for embedding the gate electrodes 5 has a width of 1 μm in a width direction and a depth of 5 μm in a depth direction. For example, the gate electrodes 5 are formed of polysilicon in which an impurity is introduced. However, the material of the gate electrodes 5 may not be limited to the polysilicon, and the gate electrodes 5 may be formed of another semiconductor material or a conductive material.

For example, the gate electrodes 5 are arrayed in a mesh formation in a plan view. One of the photodetectors 1 is formed in each of regions surrounded by the trench in which the gate electrodes 5 are embedded. An upper end of each gate electrode 5 is embedded from the upper surface of the epitaxial layer 3b toward the side of the silicon substrate 3a. The upper portion of each gate electrode 5 is covered by an embedded insulation layer which is embedded in the trench after formation of the gate electrode 5.

The gate insulation film 7 is arranged between the gate electrode 5 and the epitaxial layer 3b. The epitaxial layer 3b and the gate electrode 5 are insulated by the gate insulation film 7. The gate insulation film 7 is formed of a silicon oxide film having a thickness of 20 nm. However, the material of the gate insulation film 7 is not limited to the silicon oxide film, but may be a material capable of insulating the epitaxial layer 3b and the gate electrode 5.

The emitter region 9 (N+) is formed in the surface of the epitaxial layer 3b. The emitter region 9 is formed for each of the photodetectors 1. The emitter region 9 is formed by introducing an N type impurity (of the first conductivity type) into the epitaxial layer 3b. The emitter region 9 is arranged so that the emitter region 9 is separated from the gate insulation film 7. The bottom of the emitter region 9 is located at a position above the upper end of the gate electrode 5.

The base region 11 (P) is formed in the epitaxial layer 3b at a position below the emitter region 9. The base region 11 is formed in each of the photodetectors 1. The base region 11 is formed by introducing a P type impurity (of the second conductivity type) into the epitaxial layer 3b. The base region 11 is adjacent to both the gate insulation film 7 and the emitter region 9. The bottom of the base region 11 is located at a position above a lower end of the gate electrode 5.

The collector region 13 (N−) is formed by a portion of the epitaxial layer 3b below the base region 11. The collector region 13 is adjacent to both the gate insulation film 7 and the base region 11. The bottom of the collector region 13 is located at a position below the lower end of the gate electrode 5. The collector region 13 is formed to be continuous between the adjacent photodetectors 1 at a position below the gate electrodes 5. The silicon substrate 3a is located at a position below the collector region 13.

An inclined impurity concentration profile is provided for the emitter region 9, the base region 11, and the collector region 13, so that a concentration of the impurity in the base region 11 is high on the side of the surface of the epitaxial layer 3b and is low on the side of the silicon substrate 3a.

An interlayer insulation film 15 is formed on the epitaxial layer 3b. Contact holes 17 are formed in the interlayer insulation film 15. The contact holes 17 are arranged above the emitter region 9. The contact holes 17 are filled with a conductive material, such as tungsten or aluminum.

A metal wiring pattern 19 which is made of, for example, aluminum is formed on the interlayer insulation film 15. The metal wiring pattern 19 is electrically connected to the emitter region 9 via the conductive material contained in the contact holes 17. Note that an electric potential is supplied to the gate electrode 5 at a position (not shown) outside the area shown in FIGS. 1 and 2. A protection film or the like is formed on the interlayer insulation film 15.

The photodetector (semiconductor device) 1 according to the embodiment has a vertical bipolar transistor structure which includes the emitter region 9, the base region 11, and the collector region 13. In this bipolar transistor, the current amplification factor varies as the width of a quasi-neutral base region varies. In the photodetector 1, when a voltage is supplied to the gate electrode 5, the width of the depletion layer of the quasi-neutral base region near the gate electrode 5 is varied, and so the current amplification factor is varied.

In the photodetector 1 according to the embodiment, a parasitic MOS transistor may be formed with a configuration including the gate electrode 5, the gate insulation film 7, the emitter region 9 (source), the base region 11 (channel), and the collector region 13 (drain).

In the photodetector 1 according to the embodiment, a structure in which the upper end of the gate electrode 5 is separated from the emitter region 9 is used. Taking into consideration the positional relationship between the gate electrode 5 and the emitter region 9 in the depth direction, the upper end of the gate electrode 5 is located at a position below the lower part of the emitter region 9. Hence, a smallest distance between the gate electrode 5 and the base-emitter interface of the base region 11 and the emitter region 9 is greater than a smallest distance between the gate electrode 5 and the base region 11.

For this reason, in the photodetector 1 according to the embodiment, even if an N type inversion layer or channel is present in the base region 11 when supplying the voltage to the gate electrode 5, the N type inversion layer or channel is not present in the base-emitter interface of the base region 11 and the emitter region 9. Hence, it is possible for the photodetector 1 according to the embodiment to prevent the flowing of the leakage current through the parasitic MOS transistor. Namely, the photodetector 1 according to the embodiment provides an increased current amplification factor and prevents the leakage current without increasing the dark current.

It is preferred that the distance (the smallest distance) between the upper end of the gate electrode 5 and the emitter region 9 is set to a smaller distance that the inversion layer or channel induced by the electric field of the gate electrode does not reach the emitter region 9. The distance between the upper end of the gate electrode 5 and the emitter region 9 varies depending on the thickness of the gate insulation film 7, the channel density and the amplitude of the voltage supplied to the gate electrode 5. For example, this distance may be in a range of 0.2 to 0.5 μm if the thickness of the gate insulation film 7 is in a range of 20 to 50 nm and the channel density is in a range of 1×10¹⁶ to 1×10¹⁷ cm⁻³.

In the photodetector 1 according to the embodiment, even if the structure in which the gate electrode 5 is separated from the emitter region 9 is used, the voltage is supplied to the gate electrode 5 and the depletion layer is extended to the base region 11 so that the current amplification factor of the phototransistor may be increased to provide an increased photoelectric current.

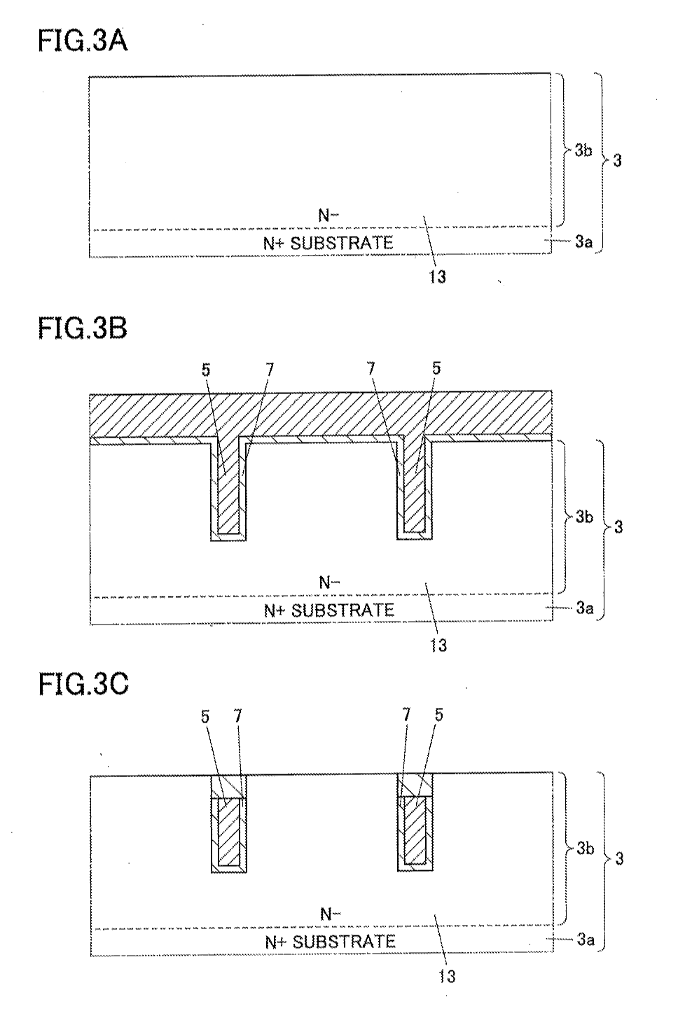

FIGS. 3A-3C, 4A-4C, 5A and 5B are diagrams for explaining a method of manufacturing the semiconductor device (the photodetector 1) according to the embodiment which is described above with reference to FIGS. 1 and 2. The method of manufacturing the photodetector 1 according to the embodiment will be described with reference to FIGS. 3A-3C, 4A-4C, 5A and 5B.

As shown in FIG. 3A, a semiconductor substrate 3 in which an N type epitaxial layer 3b (which forms the collector region 13 in FIG. 1) is deposited on an N type silicon substrate 3a having a low resistance is prepared. For example, the silicon substrate 3a has a specific resistance of 6 mΩcm (milliohm-cm), the epitaxial layer 3b has a specific resistance of 1 Ωcm (ohm-cm), and the epitaxial layer 3b has a thickness of 20 μm.

As shown in FIG. 3B, a trench for embedding the gate electrodes 5 (which are shown in FIG. 1) is formed on a surface of the epitaxial layer 3b by performing a known fabrication process. A gate insulation film 7 is deposited on the surface of the epitaxial layer 3b and a doped polysilicon is embedded in the trench portions via the gate insulation film 7 to form the gate electrodes 5. For example, the trench has a width of 1 μm and a depth of 5 μm, and the gate insulation film 7 has a thickness of 20 nm.

As shown in FIG. 3C, an etch-back process is performed on the doped polysilicon to etch the upper portion of each gate electrode 5 until the etched upper portion of each gate electrode 5 is located at a position below an emitter bonding depth. Thereafter, an embedded insulation layer which is made of, for example, a silicon oxide film is embedded in the upper portion of the trench. Note that the emitter bonding depth refers to a depth position of the interface (or the bonded area) between the emitter region 9 and the base region 11 as shown in FIG. 1.

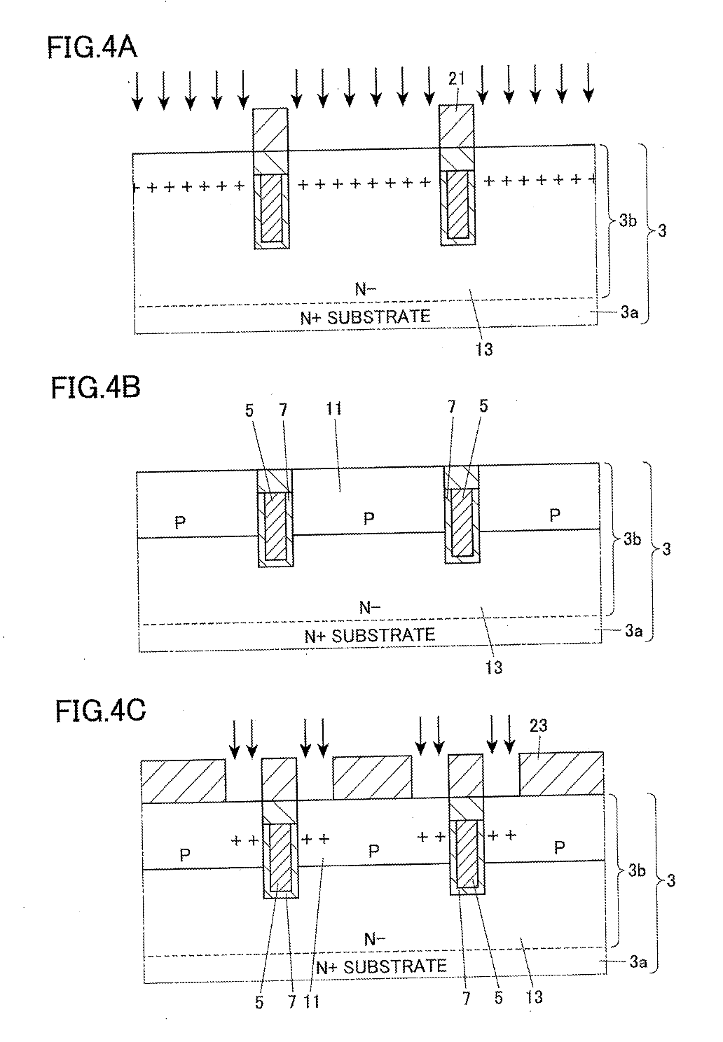

As shown in FIG. 4A, a mask film 21 is formed on the epitaxial layer 3b. For example, the mask film 21 may be a 400-nm-thick silicon oxide film. By performing a photolithographic process and an etching process, an opening is formed in the mask film 21 in a position corresponding to a formation area of the photodetector 1 (see FIG. 1). By performing an ion implantation process, a P type impurity (indicated by “+” in FIG. 4A), such as boron ions, is implanted in the epitaxial layer 3b through the opening of the mask film 21 to form a P type base region in which the P type impurity is introduced. For example, the boron ion implanting conditions may be indicated by an accelerating energy of 30 keV and a dose amount of 3.2×10¹³ cm⁻².

As shown in FIG. 4B, in the state where the mask film 21 is left, a thermal diffusion process is performed on the P type impurity implanted at the step shown in FIG. 4A, to form the base region 11. For example, the conditions of the thermal diffusion process may be indicated by a heating temperature of 1150° C. and a heating period of 50 minutes. Thereafter, the mask film 21 is removed.

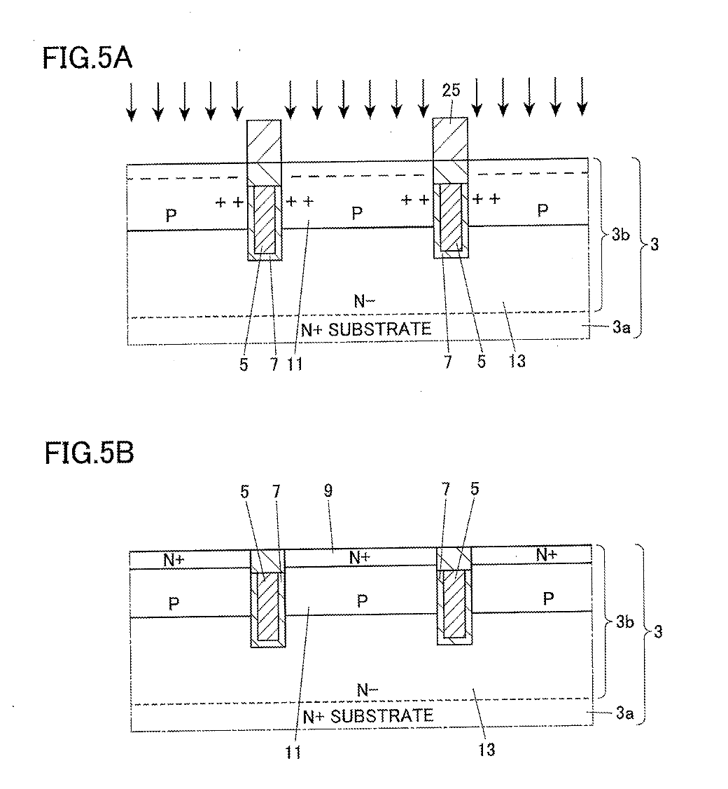

As shown in FIG. 4C, a mask film 23 including openings in the vicinity of the gate electrode 5 is formed on the base region 11. By performing an ion implantation process, a P type impurity (indicated by “+” in FIG. 4C), such as boron ions, is implanted in the epitaxial layer 3b (or the base region 11) via the openings of the mask film 23. The boron ion implantation process is performed such that the boron ions are implanted in the epitaxial layer 3b at a deep position below a position where an N type impurity is subsequently implanted at a step shown in FIG. 5A which will be described later. For example, the boron ion implanting conditions may be indicated by an accelerating energy of 180 keV and a dose amount of 1.0×10¹³ cm⁻².

As shown in FIG. 5A, the mask film 23 is removed. A mask film 25 including an opening above the base region 11 is formed. By performing an ion implantation process, an N type impurity (indicated by “−” in FIG. 5A), such as phosphorous ions, is implanted in the epitaxial layer 3b (the base region 11) via the opening of the mask film 25. For example, the phosphorus ion implanting conditions may be indicated by an accelerating energy of 50 keV and a dose amount of 6.0×10¹⁵ cm⁻².

As shown in FIG. 5B, in the state in which the mask film 25 is left, a heat treatment is performed to activate the P type impurity and the N type impurity which are introduced in the epitaxial layer 3b at the steps shown in FIG. 4C and FIG. 5A, so that the emitter region 9 is formed on the base region 11. For example, the conditions of the heat treatment may be indicated by a heating temperature of 920° C. and a heating period of 40 minutes. Thereafter, the mask film 25 is removed.

Further, by performing a known fabrication process, an interlayer insulation film 15, a contact hole 17, a metal wiring pattern 19, and a protection film are formed on the epitaxial layer 3b in this order (see FIG. 1). Note that the method of manufacturing the semiconductor device (the photodetector 1 shown in FIG. 1) according to the invention is not limited to the manufacturing method which is described above with reference to FIGS. 3A-3C, 4A-4C, 5A and 5B.

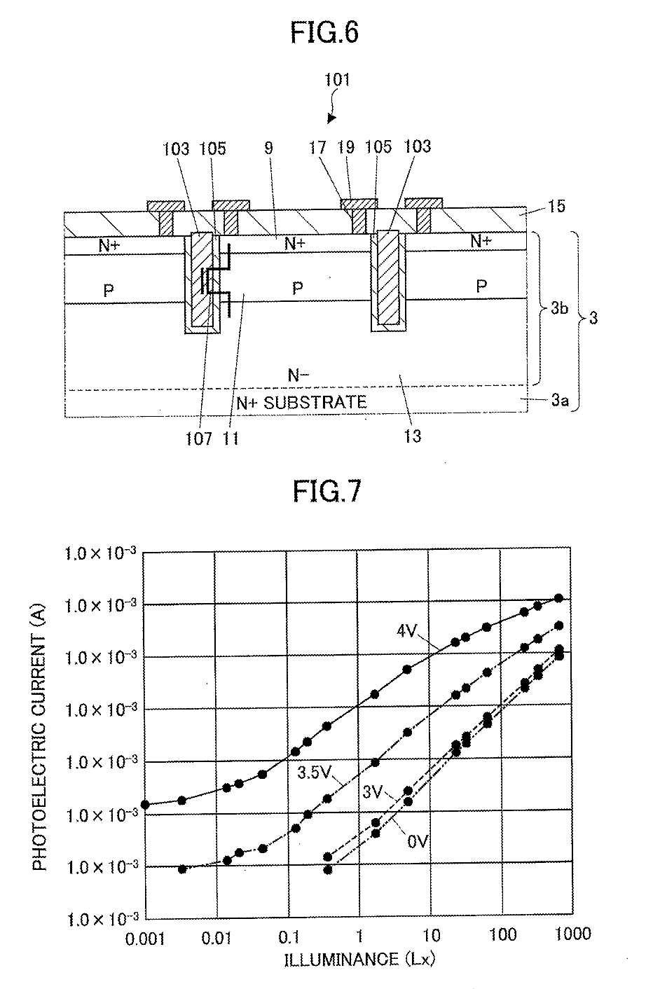

FIG. 6 is a cross-sectional view of a photodetector 101 as a reference example. In FIG. 6, the elements which are essentially the same as corresponding elements in FIG. 1 are designated by the same reference numerals, and a description thereof will be omitted.

As shown in FIG. 6, the photodetector 101 differs from the photodetector 1 shown in FIG. 1 in that the depth positions of a gate electrode 103 and a gate insulation film 105 are different. In this reference example, an upper end of the gate electrode 103 and an upper end of the gate insulation film 105 are arranged in the vicinity of the surface of the epitaxial layer 3b.

The gate insulation film 105 which is in contact with the side of the gate electrode 103 has an almost uniform thickness. In this photodetector 101, a smallest distance between the gate electrode 103 and the base-emitter interface of the base region 11 and the emitter region 9 is the same as a smallest distance between the gate electrode 103 and the base region 11.

In the photodetector 101, a parasitic MOS transistor 107 is formed which includes the gate electrode 103, the gate insulation film 105, the emitter region 9, the base region 11, and the collector region 13.

FIG. 7 is a diagram for explaining a relationship between illuminance and photoelectric current of a photodetector having a vertical bipolar transistor structure according to a gate electrode voltage of the photodetector. In FIG. 7, the vertical axis indicates the photoelectric current (in ampere (A)), and the horizontal axis indicates the illuminance (in lux (Lx)). The gate electrode voltage is set to four different values: 0 V, 3 V, 3.5 V, and 4 V.

As shown in FIG. 7, in the photodetector having the vertical bipolar transistor structure, the current amplification factor varies depending on the amplitude of the voltage supplied to the gate electrode. In the photodetector 101, however, the parasitic MOS transistor 107 is formed as shown in FIG. 6.

In the photodetector 101, if the voltage is supplied to the gate electrode 103, the parasitic MOS transistor 107 operates simultaneously with the bipolar transistor operation. Hence, when the photodetector 101 operates as a phototransistor, an electric current sent from the parasitic MOS transistor 107 is undesirably added to a photoelectric current generated by the photodetector 101 at a time of light irradiation. Because of this, the dark current in the photodetector 101 is serious and the light-receiving sensitivity of the photodetector 101 at a low illumination is lower than that of the photodetector 1 shown in FIG. 1.

A threshold of the parasitic MOS transistor 107 is affected by the conditions of forming the impurity concentration profile in the base region 11 which are associated with the current amplification factor of the photodetector 101, and it is very difficult to independently control only the parasitic MOS transistor 107. For example, there may be a case in which the impurity concentration of the base region 11 is reduced in order to optimize the current amplification factor. Further, there may be another case in which the ratio of the region occupied by the parasitic MOS transistor 107 to the whole cell region is increased relatively by the miniaturization of the cells. In this case, the contribution to the dark current of the parasitic MOS transistor 107 will become large and the dark current of the whole cell region will increase.

In view of the above problem, the photodetector 1 according to the embodiment described above with reference to FIGS. 1 and 2 is capable of preventing the formation of the parasitic MOS transistor and providing an increased current amplification factor without increasing the dark current.

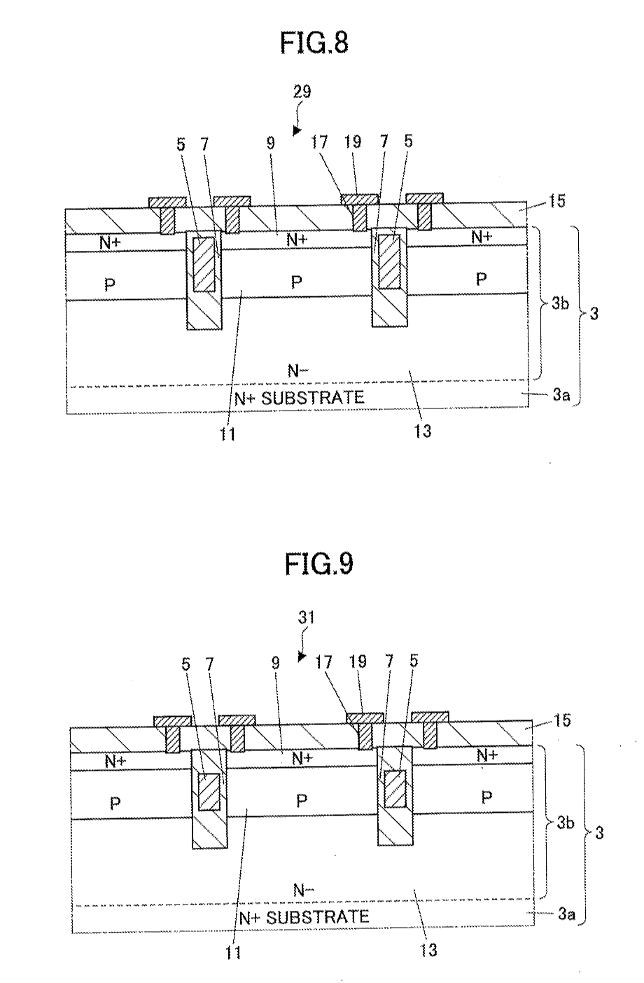

FIG. 8 is a cross-sectional view of a photodetector 29 according to another embodiment. In FIG. 8, the elements which are essentially the same as corresponding elements in FIG. 1 are designated by the same reference numerals, and a description thereof will be omitted.

As shown in FIG. 8, the photodetector 29 according to this embodiment differs from the photodetector 1 shown in FIG. 1 in that the gate electrodes 5 of this embodiment are arranged so that an upper end and a lower end of each gate electrode 5 are located at a position above the position where the upper end and the lower end of the gate electrode 5 in the photodetector 1 of FIG. 1 are located. Specifically, the upper end of the gate electrode 5 of this embodiment is located at a position above the bottom of the emitter region 9 and the top of the base region 11. The lower end of the gate electrode 5 of this embodiment is located at a position above the bottom of the base region 11 and the top of the collector region 13.

In the photodetector 29 of this embodiment, a structure in which the lower end of the gate electrode 5 is separated from the collector region 13 is used. A distance between the gate electrode 5 and the base-collector interface of the base region 11 and the collector region 13 is greater than a distance between the gate electrode 5 and the base region 11. Namely, the gate electrode 5 is arranged in a position where the formation of an inversion layer in the base-collector interface of the base region 11 and the collector region 13 may be prevented by controlling the magnitude of the voltage supplied to the gate electrode 5, although the inversion layer is formed in the base region 11.

The photodetector 29 of this embodiment is configured so that a state where an N type inversion layer or channel is not formed in the base-collector interface of the base region 11 and the collector region 13 may be maintained even if the N type inversion layer or channel is formed in the base region 11. Hence, similar to the photodetector 1 shown in FIG. 1, the photodetector 29 is capable of preventing the flowing of the leakage current through the parasitic MOS transistor. The photodetector 29 is capable of providing an increased current amplification factor without increasing the dark current.

Further, in the photodetector 29 of this embodiment, the gate electrode 5 and the collector region 13 as an output terminal where an electric field is generated do not overlap with respect to the horizontal direction, and the photodetector 29 is capable of preventing the leakage current in the opposite direction between the base region 11 and the collector region 13. As a result, it is possible to prevent the omission of accumulated charge in the base region 11 in an OFF state of the phototransistor.

It is preferred that the distance (the smallest distance) between the lower end of the gate electrode 5 and the collector region 13 is set to a smaller distance so that the inversion layer or channel induced by the electric field of the gate electrode does not reach the collector region 13, without increasing the leakage current in the collector and base junction. For example, this distance may be in a range of 0.5 to 1.0 μm if the thickness of the gate insulation film 7 is in a range of 20 to 50 nm and the channel density is in a range of 1×10¹⁶ to 1×10¹⁷ cm⁻³.

In the photodetector 29 of this embodiment, even if the structure in which the gate electrode 5 is separated from the collector region 13 is used, the voltage is supplied to the gate electrode 5 and the depletion layer is extended to the base region 11 so that the current amplification factor of the phototransistor may be increased to provide an increased photoelectric current.

For example, the gate electrode 5 of the photodetector 29 may be formed by embedding the embedded insulation layer, before embedding the gate electrode 5 in the trench at the step shown in FIG. 3B, and thereafter embedding the gate electrode 5 in the trench. Further, when performing the etch-back process on the doped silicon similar to the step shown in FIG. 3C, the etch-back process is performed until the etched upper end of the gate electrode 5 is located at a position below the emitter bonding depth. The method of forming the gate electrode 5 in the photodetector 29 is not limited to this example.

FIG. 9 is a cross-sectional view of a photodetector 31 according to another embodiment. In FIG. 9, the elements which are essentially the same as corresponding elements in FIG. 1 are designated by the same reference numerals, and a description thereof will be omitted.

As shown in FIG. 9, the photodetector 31 of this embodiment differs from the photodetector 1 shown in FIG. 1 in that the gate electrodes 5 of this embodiment are arranged so that a lower end of each gate electrode 5 is located at a position above the position where the lower end of the gate electrode 5 in the photodetector 1 of FIG. 1 is located. For example, the lower end of the gate electrode 5 of this embodiment may be located at the position which is the same as the position where the lower end of the gate electrode 5 of the photodetector 29 of FIG. 8 is located.

According to the photodetector 31 of this embodiment, both the advantageous features of the photodetector 1 described above with reference to FIGS. 1-2 and the advantageous features of the photodetector 29 described above with reference to FIG. 8 can be provided. Note that the distance (the smallest distance) between the upper end of the gate electrode 5 and the emitter region 9 and the distance (the smallest distance) between the lower end of the gate electrode 5 and the collector region 13 in this embodiment may be in conformity with the distances in the above-described embodiment of FIGS. 1-2 and the distances in the above-described embodiment of FIG. 8.

For example, the gate electrode 5 of the photodetector 31 may be formed by embedding the embedded insulation layer, before embedding the gate electrode 5 in the trench at the step shown in FIG. 3B, and thereafter embedding the gate electrode 5 in the trench. The method of forming the gate electrode 5 in the photodetector 31 is not limited to this example.

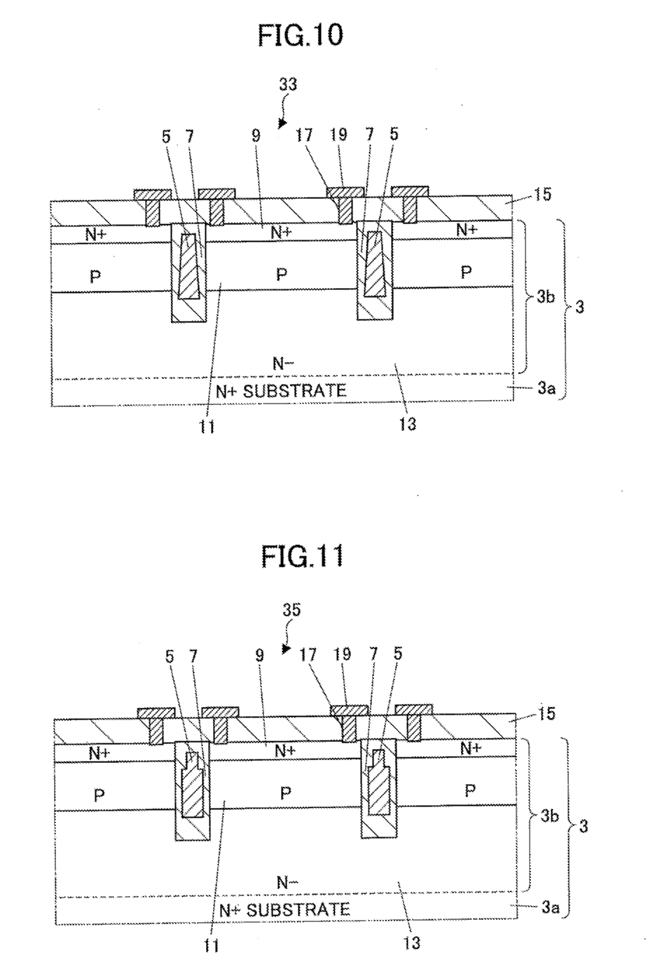

Next, several photodetectors according to other embodiments including different cross-sectional shapes of each of a plurality of gate electrodes and being capable of providing the advantageous features similar to those of the photodetector 1 shown in FIG. 1 will be described with reference to FIGS. 10-14.

FIG. 10 is a cross-sectional view of a photodetector 33 according to another embodiment. FIG. 11 is a cross-sectional view of a photodetector 35 according to another embodiment. In FIGS. 10 and 11, the elements which are essentially the same as corresponding elements in FIG. 1 are designated by the same reference numerals, and a description thereof will be omitted.

The photodetector 33 shown in FIG. 10 differs from the photodetector 1 shown in FIG. 1 in that each of the gate electrodes 5 of this embodiment is arranged to have an upper-end position and a cross-sectional shape of the gate electrode 5, which are different from the upper-end position and the cross-sectional shape of each gate electrode in the photodetector 1 shown in FIG. 1. The photodetector 35 shown in FIG. 11 also differs from the photodetector 1 shown in FIG. 1 in that each of the gate electrodes 5 of this embodiment is arranged to have an upper-end position and a cross-sectional shape of the gate electrode 5, which are different from the upper-end position and the cross-sectional shape of each gate electrode in the photodetector 1 shown in FIG. 1. Specifically, the upper end of the gate electrode 5 in the photodetector 33 and the upper end of the gate electrode 5 in the photodetector 35 are located at a position above the bottom of the emitter region 9.

As shown in FIG. 10, the cross-sectional shape of the gate electrode 5 of the photodetector 33 is a trapezoidal shape in which an upper base of the trapezoid is smaller in width than a lower base of the trapezoid. As shown in FIG. 11, the cross-sectional shape of the gate electrode 5 of the photodetector 35 is a convex configuration including an upward convex portion on the upper side.

In the photodetectors 33 and 35, a structure in which the gate electrode 5 is separated from the emitter region 9 in a horizontal direction is used. Taking into consideration the positional relationship between the gate electrode 5, the emitter region 9, and the base region 11 in the horizontal direction, a smallest distance between the gate electrode 5 and the bottom of the emitter region 9 is greater than a smallest distance between the gate electrode 5 and the base region 11. Namely, in the photodetectors 33 and 35, a smallest distance between the gate electrode 5 and the base-emitter interface of the base region 11 and the emitter region 9 is greater than a smallest distance between the gate electrode 5 and the base region 11. Hence, the photodetectors 33 and 35 are also capable of providing the advantageous features similar to those of the photodetector 1 described above with reference to FIG. 1.

It is preferred to set up the fabrication process conditions for the structure of the photodetectors 33 and 35 such that no channel is formed in the emitter bonding end face by reducing the electric field on the channel surface.

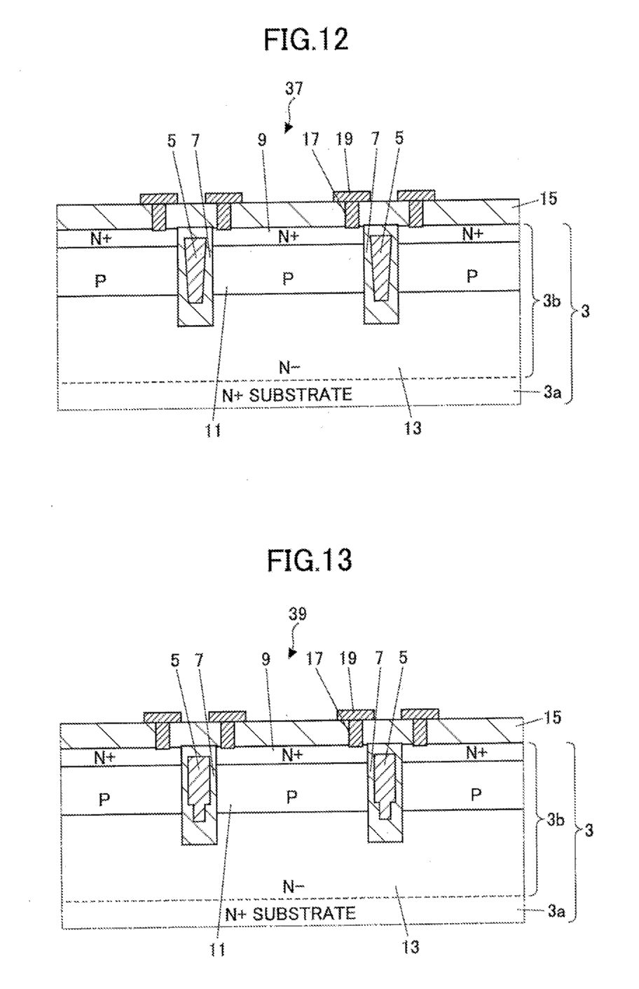

FIG. 12 is a cross-sectional view of a photodetector 37 according to another embodiment. FIG. 13 is a cross-sectional view of a photodetector 39 according to another embodiment. In FIGS. 12 and 13, the elements which are essentially the same as corresponding elements in FIG. 1 are designated by the same reference numerals, and a description thereof will be omitted.

The photodetector 37 shown in FIG. 12 differs from the photodetector 1 shown in FIG. 1 in that each of the gate electrodes 5 of this embodiment is arranged to have an upper-end position and a cross-sectional shape of the gate electrode 5, which are different from the upper-end position and the cross-sectional shape of each gate electrode 5 in the photodetector 1 shown in FIG. 1. The photodetector 39 shown in FIG. 13 differs from the photodetector 1 shown in FIG. 1 in that each of the gate electrodes 5 of this embodiment is arranged to have an upper-end position and a cross-sectional shape of the gate electrode 5, which are different from the upper-end position and the cross-sectional shape of each gate electrode 5 in the photodetector 1 shown in FIG. 1. Specifically, the upper end of the gate electrode 5 in the photodetector 37 and the upper end of the gate electrode 5 in the photodetector 39 are located at a position above the bottom of the emitter region 9.

As shown in FIG. 12, the cross-sectional shape of the gate electrode 5 of the photodetector 37 is a trapezoidal shape in which an upper base of the trapezoid is greater in width than a lower base of the trapezoid. As shown in FIG. 13, the cross-sectional shape of the gate electrode 5 of the photodetector 39 is a convex configuration including a downward convex portion on the lower side.

In the photodetectors 37 and 39, a structure in which the gate electrode 5 is separated from the collector region 13 in a horizontal direction is used. Taking into consideration the positional relationship between the gate electrode 5, the base region 11, and the collector region 13 in the horizontal direction, a smallest distance between the gate electrode 5 and the top of the collector region 13 is greater than a smallest distance between the gate electrode 5 and the base region 11. Namely, in the photodetectors 37 and 39, a smallest distance between the gate electrode 5 and the base-collector interface of the base region 11 and the collector region 13 is greater than a smallest distance between the gate electrode 5 and the base region 11. Hence, the photodetectors 37 and 39 are also capable of providing the advantageous features similar to those of the photodetector 29 described above with reference to FIG. 8.

It is preferred to set up the fabrication process conditions for the structure of the photodetectors 37 and 39 such that no channel is formed in the collector bonding end face by reducing the electric field on the channel surface.

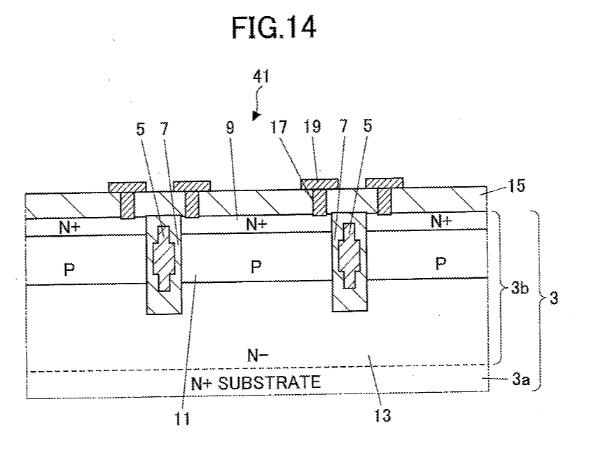

FIG. 14 is a cross-sectional view of a photodetector 41 according to another embodiment. In FIG. 14, the elements which are essentially the same as corresponding elements in FIG. 1 are designated by the same reference numerals, and a description thereof will be omitted.

As shown in FIG. 14, the cross-sectional shape of the gate electrode 5 of the photodetector 41 may be a convex configuration including an upward convex portion on the upper side and a downward convex portion on the lower side.

In the photodetector 41 of this embodiment, a smallest distance between the gate electrode 5 and the base-emitter interface of the base region 11 and the emitter region 9 and a smallest distance between the gate electrode 5 and the base-collector interface of the base region 11 and the collector region 13 are greater than a smallest distance between the gate electrode 5 and the base region 11. Hence, the photodetector 41 is also capable of providing the advantageous features similar to those of the photodetector 31 described above with reference to FIG. 9.

In the embodiment shown in FIG. 14, the cross-sectional shape of the gate electrode 5 is the convex configuration including the upward convex portion on the upper side and the downward convex portion on the lower side. In this embodiment, at least one of the upward convex portion and the downward convex portion in the convex configuration may have a trapezoidal shape in which a width dimension of the upper or lower end face is smaller than that of the middle portion thereof.

Note that the cross-sectional shape of the gate electrode 5 is not limited to the convex configurations shown in FIGS. 11, 13 and 14. Alternatively, the cross-sectional shape of the gate electrode 5 may be other convex configurations, such as a convex configuration having an acute-angled end portion and a convex configuration having a rounded end portion.

Further, the upper-end and lower-end positions in the depth direction of the gate electrode 5 of any of the embodiments described above with reference to FIGS. 1, 8 and 9 may be applied to the upper-end and lower-end positions in the depth direction of the gate electrode 5 of each of the embodiments described above with reference to FIGS. 10-14. Such modified photodetectors are also capable of providing the advantageous features similar to those of the above-described embodiments.

As described in the foregoing, according to the invention, it is possible to provide a semiconductor device which is capable of providing an increased current amplification factor and preventing the leakage current.

The semiconductor device according to the invention is not limited to the above-described embodiments, and variations and modifications may be made without departing from the scope of the present invention. It is to be understood that the foregoing detailed description is exemplary and explanatory and is not restrictive of the invention as claimed.

For example, in the above-mentioned embodiments, it is assumed that the photodetector is an NPN bipolar transistor. However, the semiconductor device according to the invention may be a PNP bipolar transistor. For example, such PNP bipolar transistor may be implemented by reversing the conductivity type used in the NPN bipolar transistors in the foregoing embodiments to the opposite conductivity type.

Further, in the foregoing embodiments, the gate electrode 5 is provided to have a frame configuration or a grid configuration in a plan view. However, the photodetector according to the invention is not limited to these examples. The gate electrode in the photodetector according to the invention may have a configuration which is neither a frame configuration nor a grid configuration in a plan view and includes a partially cut frame portion.

Further, in the foregoing embodiments, the plural photodetectors 5 are arrayed in a matrix formation. However, the photodetector according to the invention is not limited to these embodiments. The arrangement of the photodetectors according to the invention may be arbitrary. For example, the photodetectors may be arrayed in a honeycomb formation. Moreover, another element, such as a transistor for a read-out switch, may be included in a region of the array of the photodetectors.

In the foregoing description, it is assumed that the photodetectors are the embodiments of the semiconductor device according to the invention. However, the semiconductor device according to the invention may also be applicable to semiconductor devices other than the photodetectors.

What is claimed is:

1. A semiconductor device comprising:
a semiconductor layer;
an electrode embedded from a surface of the semiconductor layer to an inside of the semiconductor layer and insulated by an insulation layer;
a structure in which a first semiconductor region of a first conductivity type, a second semiconductor region of a second conductivity type, and a third semiconductor region of the first conductivity type are formed in this order from the surface of the semiconductor layer along the electrode via the insulation layer;
wherein the electrode is arranged at a position where no inversion layer is formed by a voltage supplied to the electrode in at least one of an interface of the first semiconductor region and the second semiconductor region and an interface of the second semiconductor region and the third semiconductor region.

2. A semiconductor device comprising:
a semiconductor layer;
an electrode embedded from a surface of the semiconductor layer to an inside of the semiconductor layer and insulated by an insulation layer;
a structure in which a first semiconductor region of a first conductivity type, a second semiconductor region of a second conductivity type, and a third semiconductor region of the first conductivity type are formed in this order from the surface of the semiconductor layer along the electrode via the insulation layer;
wherein at least one of a distance between the electrode and an interface of the first semiconductor region and the second semiconductor region and a distance between the electrode and an interface of the second semiconductor region and the third semiconductor region is greater than a distance between the electrode and the second semiconductor region.

3. The semiconductor device according to claim 1, wherein, with respect to a positional relationship between the electrode and the first semiconductor region in a depth direction, an upper end of the electrode is located at a position below a bottom of the first semiconductor region.

4. The semiconductor device according to claim 1, wherein, with respect to a positional relationship between the electrode and the third semiconductor region in a depth direction, a lower end of the electrode is located at a position above a top of the third semiconductor region.

5. The semiconductor device according to claim 1, wherein, with respect to a positional relationship between the electrode, the first semiconductor region, and the second semiconductor region in a horizontal direction, a distance between the electrode and a bottom of the first semiconductor region is greater than a distance between the electrode and the second semiconductor region.

6. The semiconductor device according to claim 5, wherein a cross-sectional shape of the electrode is either a trapezoidal shape in which an upper base is smaller in width than a lower base or a convex configuration including an upward convex portion on an upper side of the configuration.

7. The semiconductor device according to claim 1, wherein, with respect to a positional relationship between the electrode, the second semiconductor region, and the third semiconductor region in a horizontal direction, a distance between the electrode and a top of the third semiconductor region is greater than a distance between the electrode and the second semiconductor region.

8. The semiconductor device according to claim 7, wherein a cross-sectional shape of the electrode is either a trapezoidal shape in which an upper base is greater in width than a lower base or a convex configuration including a downward convex portion on a lower side of the configuration.

9. The semiconductor device according to claim 1, wherein a current amplification factor of the semiconductor device is variable depending on an amplitude of the voltage supplied to the electrode.

10. The semiconductor device according to claim 1, wherein the electrode is provided to have a frame configuration in a plan view of the semiconductor layer.

11. An imaging apparatus comprising a photodetector which is constituted by the semiconductor device according to claim 1.

12. A method of manufacturing a semiconductor device including
a semiconductor layer,
an electrode embedded from a surface of the semiconductor layer to an inside of the semiconductor layer and insulated by an insulation layer, and
a structure in which a first semiconductor region of a first conductivity type, a second semiconductor region of a second conductivity type, and a third semiconductor region of the first conductivity type are formed in this order from the surface of the semiconductor layer along the electrode via the insulation layer,
the method of manufacturing the semiconductor device comprising:
arranging the electrode at a position where no inversion layer is formed by a voltage supplied to the electrode in at least one of an interface of the first semiconductor region and the second semiconductor region and an interface of the second semiconductor region and the third semiconductor region.
